(19) United States
(12) Patent Application Publication
(10) Pub. No.: US 2025/0160154 A1
(43) Pub. Date: May 15, 2025

(54) DISPLAY PANEL AND METHOD OF MANUFACTURING THE SAME

(71) Applicant: HKC CORPORATION LIMITED, SHENZHEN (CN)

(72) Inventors: Dongmei WEI, SHENZHEN (CN); Zhonglin CAO, SHENZHEN (CN); Wenyu YI, SHENZHEN (CN); Yajuan FENG, SHENZHEN (CN); Jie CHEN, SHENZHEN (CN); Haijiang YUAN, SHENZHEN (CN)

(73) Assignee: HKC CORPORATION LIMITED, SHENZHEN (CN)

(21) Appl. No.: 18/946,974

(22) Filed: Nov. 14, 2024

(30) Foreign Application Priority Data
Nov. 14, 2023 (CN) 202311519099.1

(51) Int. Cl. H10K 59/131; H10K 59/12; H10K 59/122; H10K 59/80; H10K 77/10; H10K 102/00

(52) U.S. Cl. CPC H10K 59/131; H10K 59/1201; H10K 59/122; H10K 59/873; H10K 77/111; H10K 2102/311; H10K 2102/341

(57) ABSTRACT

A display panel includes a flexible substrate, arranged with a pixel region and an extensible region; a subpixel, arranged on the pixel region, and including an anode, an organic light-emitting layer, and a cathode stacked in sequence along a direction away from the flexible substrate; and an isolation structure, arranged on the extensible region, arranged in a peripheral direction of the subpixel, and including a first insulating layer, a metal layer, and a second insulating layer stacked in sequence, where the metal layer is electrically connected to the cathode, a hole is defined on at least one of the first insulating layer and the second insulating layer, and a stress on the first insulating layer and/or the second insulating layer is released through the hole in response to the extensible region being in a stretched state. A method of manufacturing a display panel is also provided.

### CROSS REFERENCE TO RELATED APPLICATIONS

The present disclosure claims priority of Chinese Patent Application No. 202311519099.1, filed on Nov. 14, 2023, the entire contents of which are hereby incorporated by reference in their entireties.

### TECHNICAL FIELD

The present application relates to the field of display technologies, and in particular to a display panel and a method of manufacturing a display panel.

### BACKGROUND

With the upgrading of lifestyle and consumption, display products are applied more and more widely. A stretchable display technology may enable a display panel to stretch in all directions like a rubber band, so as to change shape and adapt to surfaces of arbitrary shapes. A stretchable display panel may be flexibly applied in various fields, such as consumer electronics, public displays, medical, biological, wearable, gaming, fashion, automotive scenarios, etc.

However, during a repeated stretching process, the stretchable display panel is prone to damage, resulting in decreasing the entire tensile resistance thereof, and thus the stretchable display panel is not used normally after performing repeated stretching.

### SUMMARY OF THE DISCLOSURE

According to a first aspect, the present disclosure provides a display panel. The display panel includes: a flexible substrate, arranged with a pixel region and an extensible region; a subpixel, arranged on the pixel region, and including an anode, an organic light-emitting layer, and a cathode stacked in sequence along a direction away from the flexible substrate; and an isolation structure, arranged on the extensible region, and arranged in a peripheral direction of the subpixel; where the isolation structure includes a first insulating layer, a metal layer, and a second insulating layer stacked in sequence, the metal layer is electrically connected to the cathode, a hole is defined on at least one of the first insulating layer and the second insulating layer, and a stress on the first insulating layer and/or the second insulating layer is released through the hole in response to the extensible region being in a stretched state.

According to a second aspect, the present disclosure further provides a method of manufacturing a display panel, so as to manufacture the above-mentioned display panel. The manufacturing method includes: forming the anode on the pixel region; forming the isolation structure on the extensible region, where the isolation structure is arranged in the peripheral direction of the subpixel, and includes the first insulating layer, the metal layer, and the second insulating layer stacked in sequence; forming the hole on at least one of the first insulating layer and the second insulating layer, where the stress on the first insulating layer and/or the second insulating layer is released through the hole; and forming the organic light-emitting layer and the cathode on the anode in sequence, where the cathode is electrically connected to the metal layer.

Other features and advantages of the present disclosure will be apparent through the following detailed description, or will be acquired in part by the practice of the present disclosure.

It should be understood that the above general description and the detailed description below are only illustrative and explanatory, and do not limit the present disclosure.

### BRIEF DESCRIPTION OF THE DRAWINGS

The drawings are incorporated in the specification and constitute a part of the specification, illustrate embodiments in accordance with the present disclosure and together with the description serve to explain the principle of the present disclosure. Apparently, the drawings described below only illustrate some embodiments of the present disclosure, an ordinary skilled person in the art may obtain other drawings based on these drawings, without making any creative work.

FIG. 1 is a cross-sectional schematic view of a display panel according to some embodiments of the present disclosure.

FIG. 2 is a cross-sectional schematic view of an isolation structure of the display panel according to some embodiments of the present disclosure.

FIG. 3 is a flowchart of a method of manufacturing the display panel according to some embodiments of the present disclosure.

FIG. 4 is a flowchart of a first operation of the method of manufacturing the display panel according to some embodiments of the present disclosure.

FIG. 5 is a flowchart of a second operation of the method of manufacturing the display panel according to some embodiments of the present disclosure.

FIG. 6 is a flowchart of a third operation of the method of manufacturing the display panel according to some embodiments of the present disclosure.

FIG. 7 is a flowchart of a fourth operation of the method of manufacturing the display panel according to some embodiments of the present disclosure.

FIG. 8 is a flowchart of a fifth operation of the method of manufacturing the display panel according to some embodiments of the present disclosure.

FIG. 9 is a flowchart of a sixth operation of the method of manufacturing the display panel according to some embodiments of the present disclosure.

Reference numerals in drawings: flexible substrate 100; extensible region 200; pixel region 300; pixel definition layer 310; subpixel 320; anode 321; organic light-emitting layer 322; cathode 323; insulating protection layer 324; isolation structure 330; first insulating layer 331; metal layer 332; first protruding portion 3321; second insulating layer 333; hole 340; first hole 341; second hole 342; encapsulation layer 400; second protruding portion 410.

### DETAILED DESCRIPTION

Exemplary embodiments will be described more comprehensively by referring to accompanying drawings now. However, the exemplary embodiments may be embodied in various forms and should not be limited to the embodiments set forth herein; rather, these embodiments are provided such that the present disclosure will be made thorough and complete, and the concept of exemplary embodiments will be fully conveyed to those skilled in the art.

In some embodiments, the described features, structures, or characteristics may be combined in any suitable manner in one or more embodiments. In the following description, many specific details are provided to give a full understanding of the embodiments of the present disclosure. However, those skilled in the art will realize that the technical solution of the present disclosure may be practiced without one or more specific details, or other methods, components, devices, steps, etc. In other cases, well-known methods, devices, implementations or steps are not shown or described in detail to avoid blurring various aspects of the present disclosure.

The present disclosure will be further detailed below in combination with the accompanying drawings and specific embodiments. It should be noted herein that the technical features involved in the various embodiments of the present disclosure described below combined with each other as long as they do not conflict with each other. The embodiments described below with reference to the accompanying drawings are exemplary and are intended to explain the present disclosure, and cannot be construed as limiting the present disclosure.

It should be noted that a term “a plurality of” mentioned in the present disclosure refers to two or more. A term “and/or” is only a description of an association relationship of associated objects, indicating that three relationships may exist, for example, A and/or B, which may indicate: the existence of A alone, the existence of both A and B, and the existence of B alone. In addition, a character “/” generally indicates that the front and rear associated objects are in an “or” relationship.

An organic light emitting diode (OLED) display panel is gaining increasing attention due to many advantages thereof, such as all solid state, active light-emitting, high brightness, high contrast, ultra-thin, low power consumption, no visual angle limitation, wide operating temperature range, etc. With the upgrading of lifestyle and consumption, display products are applied more and more widely. A stretchable display technology may enable a display panel to stretch in all directions like a rubber band, so as to change shape and adapt to surfaces of arbitrary shapes. A stretchable display panel may be flexibly applied in various fields, such as consumer electronics, public displays, medical, biological, wearable, gaming, fashion, automotive scenarios, etc.

However, during a repeated stretching process, the stretchable display panel is prone to damage, resulting in decreasing the entire tensile resistance thereof, and thus the stretchable display panel is not used normally after performing repeated stretching.

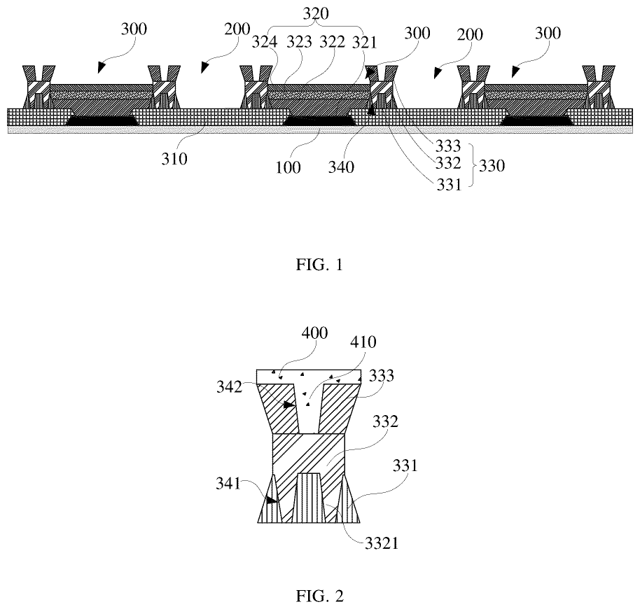

To solve the above-mentioned technical problem, as shown in FIGS. 1-2, some embodiments of the present disclosure provide a display panel. The display panel includes a flexible substrate 100, a subpixel 320, and an isolation structure 330. The flexible substrate 100 is arranged with a pixel region 300 and an extensible region 200. The subpixel 320 is arranged on the pixel region 300. The subpixel 320 includes an anode 321, an organic light-emitting layer 322, and a cathode 323 stacked in sequence along a direction away from the flexible substrate 100. The isolation structure 330 is arranged on the extensible region 200. The isolation structure 300 is arranged in a peripheral direction of the subpixel 320. The isolation structure 330 includes a first insulating layer 331, a metal layer 332, and a second insulating layer 333 stacked in sequence. The metal layer 332 is electrically connected to the cathode 323. A hole 340 is defined on at least one of the first insulating layer 331 and the second insulating layer 333. When the extensible region 200 is in a stretched state, a stress on the first insulating layer 331 and/or the second insulating layer 333 is released through the hole.

The pixel region 300 may emit light to display a color in a driving mode, and the extensible region 200 may enable the display panel to stretch in various directions, so as to change a shape of the display panel. In the pixel region 300, a plurality of subpixels 320 is formed on the pixel definition layer 310, and the isolation structure 330 is arranged in the peripheral direction of the subpixels 320, so as to isolate the plurality of subpixels 320 in a pixel accommodating region, thereby reducing the occurrence of light leakage and short circuits. The isolation structure 330 includes the first insulating layer 331, the metal layer 332, and the second insulating layer 333 stacked in sequence, and the metal layer 332 is electrically connected to the cathode 323 of the subpixel 320, thereby increasing a wire resistance of the cathode 323 and reducing a voltage drop of the cathode 323. The hole 340 is defined on at least one of the first insulating layer 331 and the second insulating layer 333. When the extensible region 200 is in the stretched state, the stress generated by stretching the extensible region 200 may be transferred to the hole 340 through the first insulating layer 331 and/or the second insulating layer 333. In this way, the stress on the first insulating layer 331 and/or the second insulating layer 333 may be released by means of deforming the hole 340.

In some embodiments, the flexible substrate 100 is a composite film layer including a nanocellulose film layer and a barrier film layer. The nanocellulose film layer is used as a main structure of the flexible substrate 100, so as to cause the flexible substrate 100 to have a good flexibility property and a good mechanical property. In addition, the barrier film layer has a good water vapor barrier effect, thereby effectively increasing the service life of the flexible substrate 100.

In some embodiments, the display panel further includes a driving circuit layer. A driving circuit is arranged on the driving circuit layer to drive the subpixel 320 to emit light.

In some embodiments, the display panel, which is an integrated structure of the substrate and the driving circuit layer, is an active OLED. The display panel with the substrate being driven by scanning through an external printed circuit board (PCB) is a passive OLED. The passive OLED includes a plurality of anodes 321 arranged in parallel and arranged at intervals, and a plurality of cathodes 323 arranged in parallel and arranged at intervals. The plurality of anodes 321 and the plurality of cathodes 323 are arranged in an intersecting way, so as to form an addressing circuit.

In some embodiments, the substrate may be a glass flexible substrate, or an organic flexible substrate. A material of the organic flexible substrate is polyimide (PI). The driving circuit layer may be a thin film transistor (TFT) circuit layer. The TFT circuit layer is configured to drive a light-emitting layer of the OLED. In some embodiments, the TFT circuit layer includes a plurality of driving circuit units arranged in an array, and each of the plurality of driving circuit units may include a TFT component and a capacitor. The each of the plurality of driving circuit units corresponds to one anode 321 and one organic light-emitting layer 322. The TFT component is a low temperature poly-silicon (LTPS) or a metal oxide semiconductor (MOS), such as a MOS of indium gallium zinc oxide (IGZO).

In some embodiments, a material of the pixel definition layer 310 may be an organic material, an organic material with an inorganic coating thereon, or an inorganic material. The organic material of the pixel definition layer 310 includes, but is not limited to, PI. The inorganic material of the definition layer 310 includes, but is not limited to, silicon oxide (SiO), silicon nitride (SiN), silicon nitride (SiNO), magnesium fluoride (MgF), or a combination thereof.

In some embodiments, the display panel includes a plurality of pixels, and the plurality of pixels are configured to emit light of different colors. The plurality of pixels emit light to display an image. Each of the plurality of pixels is composed of three subpixels 320 of red, green, and blue, and the three subpixels 320 are overlaid and mixed with each other, so as to display a white image. In addition, different color images are displayed by controlling the luminance of subpixels 320 of different colors.

In some embodiments, as shown in FIG. 1, the subpixel 320 includes the anode 321, the organic light-emitting layer 322, and the cathode 323. The anode 321 is arranged on the flexible substrate 100 disposed in the pixel accommodating region. The organic light-emitting layer 322 is arranged on the anode 321. The cathode 323 is arranged on the organic light-emitting layer 322.

In some embodiments, the anode 321 is arranged between the pixel definition layer 310 and the flexible substrate 100. The anodes 321 are arranged on a side surface of the flexible substrate 100 at intervals. A material of the anode 321 includes, but are not limited to, chromium, titanium, gold, silver, copper, aluminum, ITO, a combination thereof, or other suitable conductive material. The organic light-emitting layer 322 is configured to emit red light, blue light, or green light when energized. The organic light-emitting layer 322 may include at least one of a hole injection layer (HIL), a hole transfer layer (HTL), an emitting layer (EML), and an electron transfer layer (ETL). The cathode 323 is arranged on a side of the organic light-emitting layer 322 away from the anode 321. A material of the cathode 323 includes, but is not limited to, chromium, titanium, gold, silver, copper, aluminum, ITO, a combination thereof, or other suitable conductive material. The material of the cathode 323 may be the same as or different from that of the anode 321, which may be set according to the actual situation.

In some embodiments, an initial pixel definition layer is formed on the anode 321 of the subpixel 320, and the initial pixel definition layer is exposed and developed to form the pixel definition layer 310. In this way, it may be possible to enable the pixel definition layer 310 to form an image opening located above the anode 321 of each of the plurality of subpixels 320, and the image opening is located in the pixel accommodating area, and the pixel definition layer 310 covers a part of the anode 321 of the each of the plurality of subpixels 320. The organic light-emitting layer 322 is formed on the pixel definition layer 310 and the anode 321 by evaporating an organic light-emitting material. The cathode 323 is formed on the organic light-emitting layer 322 by evaporating a cathode material.

In some embodiments, as shown in FIG. 1, the subpixel 320 further includes an insulating protection layer 324. The insulating protection layer 324 is arranged on the cathode 323 and extends to the metal layer 332 along the isolation structure 330. The insulating protection layer 324 is configured to provide insulation protection for the cathode 323.

In some embodiments, a material of each of the first insulating layer 331 and the second insulating layer 333 may be a non-conductive organic material or a non-conductive inorganic material. The non-conductive inorganic material includes, but is not limited to, an inorganic silicon-containing material. For example, a silicon-containing material include a silicon oxide, a silicon nitride, or a combination thereof. The non-conductive organic material includes a negative photosensitive organic material. For example, the negative photosensitive organic material includes, but is not limited to, a negative photoresist.

In some embodiments, the metal layer 332 may include, but not limited to, chromium, titanium, gold, silver, copper, aluminum, ITO, a combination thereof, or other suitable conductive material, which is not limited herein.

In some embodiments, as shown in FIGS. 1-2, the hole 340 includes a first hole 341 and a second hole 342. The first hole 341 is defined on the first insulating layer 331, and the second hole 342 is defined on the second insulating layer 333. When the extensible region 200 is stretched, the stress on the first insulating layer 331 may be released through the first hole, and the stress on the second insulating layer 333 may be released through the second hole. Each of the first hole 341 and the second hole 342 may be a circular hole, a tapered hole, a trapezoidal hole, a square hole, etc. During a formation process, the each of the first hole 341 and the second hole 342 may be formed as a through hole, a semi-perforated hole, a stepped hole, etc., which is not limited herein. The first hole 341 and the second hole 342 may be formed by utilizing a process such as exposure, development, etching, etc. Since one side of the isolation structure 330 is the extensible region 200 and the other side of the isolation structure 330 is the pixel region 300, a stress on a structure of the extensible region 200 may be released through each of the first hole 341 of the first insulating layer 331 and the second hole 342 of the second insulating layer 333 when the structure of the extensible region 200 is stretched under an external force. In addition, it may be possible to enhance the tensile strength of the extensible region 200. In some embodiments, the number of the first holes 341 is two, and there is one second hole 342. The second hole 342 is arranged between the first holes 341 and is misaligned with the first holes 341.

In some embodiments, as shown in FIGS. 1-2, the first hole 341 and the second hole 342 are arranged in a same direction. The first hole 341 is misaligned with the second hole 342 in a same axis direction, such that the stress may be released at different positions, thereby dispersing the region where the stress is released. In this way, it may be possible to increase the strength of the isolation structure 330, reduce the risk of collapse of the isolation structure 330 when the stress on the first insulating layer 331 and the stress on the second insulating layer 333 are released at the same time, thus ensuring the stability of the performance of the display panel.

In some embodiments, a width of the metal layer 332 is less than a width of each of the first insulating layer 331 and the second insulating layer 333. The width of each of the first insulating layer 331 and the second insulating layer 333 is gradually decreased along a direction close to the metal layer 332. When the display panel is stretched, the stress brought by the stretching may act on the first insulating layer 331 and the second insulating layer 333 of the isolation structure 330. The stress is released through the first insulating layer 331 and the second insulating layer 333, such that each of the first insulating layer 331 and the second insulating layer 333 may release a certain displacement in a stretching direction, thereby reducing the risk of damage to the extensible region 200 during stretching and ensuring that the extensible region 200 may still be used normally after performing repeated stretching.

In some embodiments, as shown in FIGS. 1-2, a size of the first hole 341 is gradually decreased along a direction close to the pixel definition layer 310. A size of the second hole 342 is gradually decreased along a direction close to the metal layer 332. The first hole 341 and the second hole 342 are formed through etching during the manufacturing process. Therefore, the above-mentioned design may facilitate forming the structure during an etching process, so as to reduce the difficulty of forming the first hole 341 and the second hole 342.

In some embodiments, as shown in FIGS. 1-2, one side of the metal layer 332 is embedded in the first hole 341, and the other side of the metal layer 332 is a plane. The second insulating layer 333 is arranged on the plane. A first protruding portion 3321 is arranged on a side of the metal layer 332 facing the first hole 341. The first protruding portion 3321 is inserted into the first hole 341, thereby providing the isolation structure 330 with an enhanced structural strength. In this way, when the isolation structure 330 is subjected to the tensile stress, it may be possible to maintain the stability of the connection between the metal layer 332 and the first insulating layer 331. A shape of the first protruding portion 3321 is corresponding to a shape of the first hole 341. When the size of the first hole 341 is gradually decreased along the direction close to the pixel definition layer 310, a size of the first protruding portion 3321 is gradually increased along the direction close to the pixel definition layer 310. Therefore, by the above-mentioned design of the embodiments of the present disclosure, it may be possible to further increase the stability of the connection between the metal layer 332 and the first insulating layer 331.

In some embodiments, as shown in FIG. 2, the display panel further includes an encapsulation layer 400. The encapsulation layer 400 is arranged on the pixel region 300 and the extensible region 200, and is embedded in the second hole 342. The encapsulation layer 400 is arranged with a second protruding portion 410. The second protruding portion 410 is embedded in the second hole 342, such that it may be possible to enhance the stability of the connection between the encapsulation layer 400 and the second insulating layer 333. A shape of the second protruding portion 410 is corresponding to a shape of the second hole 342. When the size of the second hole 342 is gradually decreased along the direction close to the metal layer 332, a size of the second protruding portion 410 is gradually increased along the direction close to the metal layer 332. Therefore, by the above-mentioned design of the embodiments of the present disclosure, it may be possible to further increase the stability of the connection between the metal layer 332 and the first insulating layer 331.

In some embodiments, the encapsulation layer 400 is arranged on the isolation structure 330. The encapsulation layer 400 extends to the pixel region 300, so as to cause the encapsulation layer 400 to be encapsulated on the subpixel 320. The encapsulation layer 400 extends to the extensible region 200, so as to cause the encapsulation layer 400 to be filled in the extensible region 200. By arranging the encapsulation layer 400 on the pixel region 300 and the extensible region 200, it may be possible to provide protection for the pixel region 300 and the extensible region 200.

In some embodiments, as shown in FIGS. 1-2, the first hole 341 is configured to communicate with an upper surface of the first insulating layer 331 and a lower surface of the first insulating layer 331. The second hole 342 is configured to communicate with an upper surface of the second insulating layer 333 and a lower surface of the second insulating layer 333. The upper surface of the first insulating layer 331 is in communication with the lower surface of the first insulating layer 331 through the first hole 341, so as to form a through hole structure, and thus it may be possible to enable the metal layer 332 to be connected to the pixel definition layer 310. In addition, since the pixel definition layer 310 has a relatively larger area and a relatively stronger carrying capacity, the stability of the metal layer 332 may be increased. The upper surface of the second insulating layer 333 is in communication with the lower surface of the second insulating layer 333 through the second hole 342, so as to form a through hole structure, and thus it may be possible to enable the metal layer 332 to be connected to the encapsulation layer 400. In addition, based on a case that the metal layer 332 is connected to the pixel definition layer 310, the stability of the encapsulation layer 400 may be increased.

In some embodiments, the extensible region 200 is further arranged with a connecting line (not shown), and the connecting line is configured to overlap cathodes of adjacent subpixels.

In the embodiments of the present disclosure, the width of the metal layer 332 is less than the width of each of the first insulating layer 331 and the second insulating layer 333, and the width of each of the first insulating layer 331 and the second insulating layer 333 is gradually decreased along the direction close to the metal layer 332. The stress brought by the formed isolation structure 330 may act on the first insulating layer 331 and the second insulating layer 333 of the isolation structure 330 when the display panel is stretched. In this way, the stress may be released through the first insulating layer 331 and the second insulating layer 333, such that the first insulating layer 331 and the second insulating layer 333 may release the certain displacement in the stretching direction, thereby reducing the risk of damage to the extensible region 200 during stretching and ensuring that the extensible region 200 may still be used normally after performing repeated stretching. In addition, the first hole 341 of the first insulating layer 331 is misaligned with the second holes 342 of the second insulating layer 333, so as to reduce the stress concentration, thereby strengthening the strength of the isolation structure 330.

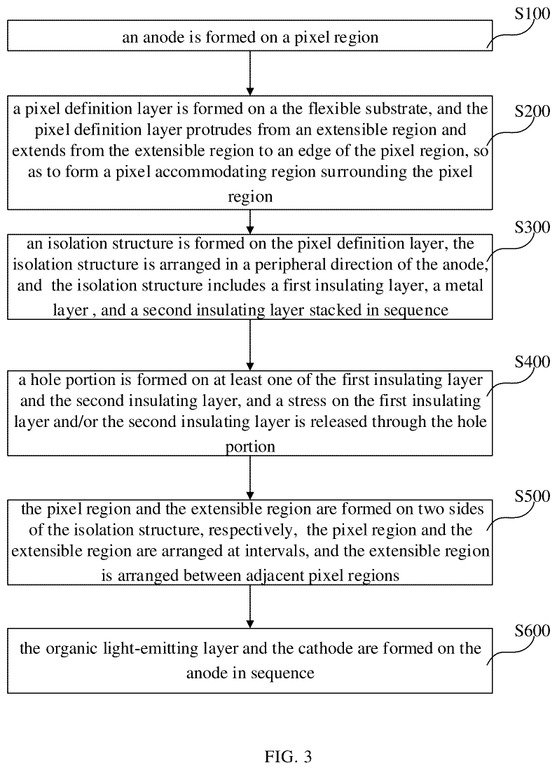

As shown in FIGS. 3-9, some embodiments of the present disclosure provide further provide a method of manufacturing a display panel, which is capable of manufacturing the above-mentioned display panel. The manufacturing method includes the following operations.

At block S100, an anode 321 is formed on a pixel region 300.

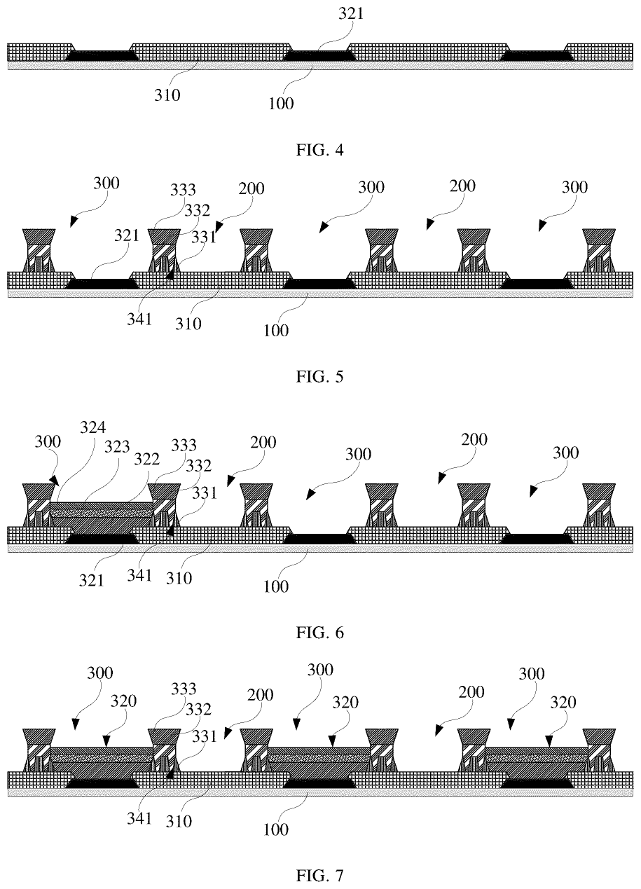

As shown in FIG. 4, the anode 321 is formed on a flexible substrate 100 by a deposition process. A material of the anode 321 includes, but are not limited to, chromium, titanium, gold, silver, copper, aluminum, ITO, a combination thereof, or other suitable conductive material.

At block S200, a pixel definition layer 310 is formed on the flexible substrate 100. The pixel definition layer 310 protrudes from an extensible region 200 and extends from the extensible region 200 to an edge of the pixel region 300, so as to form a pixel accommodating region surrounding the pixel region 300.

As shown in FIG. 4, the pixel definition layer 310 is arranged on the flexible substrate 100 and is configured to cover a part of the anode 321. A pixel opening is defined on a recessed part of the pixel definition layer 310, such that at least a part of the anode 321 is exposed in the pixel opening, such that the organic light emitting layer 322 and the cathode 323 may be formed on the anode 321 in a subsequent process. A material of the pixel definition layer 310 may be an organic material, an organic material with an inorganic coating thereon, or an inorganic material. The organic material of the pixel definition layer 310 includes, but is not limited to, PI. The inorganic material of the definition layer 310 includes, but is not limited to, silicon oxide (SiO), silicon nitride (SiN), silicon nitride (SiNO), magnesium fluoride (MgF), or a combination thereof.

At block S300, an isolation structure 330 is formed on the pixel definition layer 310. The isolation structure 300 is arranged in a peripheral direction of the anode 321. The isolation structure 330 includes a first insulating layer 331, a metal layer 332, and a second insulating layer 333 stacked in sequence.

As shown in FIG. 5, the first insulating layer 331, the metal layer 332, and the second insulating layer 333 are deposited in sequence. The process is mature, stable, and may reduce manufacturing costs.

At block S400, a hole 340 is formed on at least one of the first insulating layer 331 and the second insulating layer 333. A stress on the first insulating layer 331 and/or the second insulating layer 333 may be released through the hole.

As shown in FIG. 5, the metal layer 332 is electrically connected to the cathode 323 of the subpixel 320, thereby increasing a wire resistance of the cathode 323 and reducing a voltage drop of the cathode 323. The hole 340 is defined on at least one of the first insulating layer 331 and the second insulating layer 333. When the extensible region 200 is in the stretched state, the stress generated by stretching the extensible region 200 may be transferred to the hole 340 through the first insulating layer 331 and/or the second insulating layer 333. In this way, the stress on the first insulating layer 331 and/or the second insulating layer 333 may be released by means of deforming the hole 340.

In some embodiments, as shown in FIG. 5, a width of the metal layer 332 is less than a width of each of the first insulating layer 331 and the second insulating layer 333. The width of each of the first insulating layer 331 and the second insulating layer 333 is gradually decreased along a direction close to the metal layer 332. When the display panel is stretched, the stress brought by the stretching may act on the first insulating layer 331 and the second insulating layer 333 of the isolation structure 330. The stress is released through the first insulating layer 331 and the second insulating layer 333, such that each of the first insulating layer 331 and the second insulating layer 333 may release a certain displacement in a stretching direction, thereby reducing the risk of damage to the extensible region 200 during stretching and ensuring that the extensible region 200 may still be used normally after performing repeated stretching.

At block S500, the pixel region 300 and the extensible region 200 are formed on two sides of the isolation structure 330, respectively. The pixel region 300 and the extensible region 200 are arranged at intervals. The extensible region 200 is arranged between adjacent pixel regions 300.

As shown in FIG. 5, the extensible region 200 is arranged at intervals and is configured to provide the stretching allowance when the display panel is stretched. The pixel region 300 is configured to form the subpixel 320. When the display panel is stretched, the stretching occurs through the extensible region 200 arranged between the adjacent pixel regions 300. The pixel region 300 only experiences slight shape change, thereby maintaining a good display effect.

At block S600, the organic light-emitting layer 322 and the cathode 323 are formed on the anode 321 in sequence. The cathode 323 is electrically connected to the metal layer 332.

As shown in FIG. 6, the organic light-emitting layer 322 is firstly formed on the anode 321 by an evaporation process, and then the cathode 323 is formed on the organic light-emitting layer 322 by the evaporation process. The organic light-emitting layer 322 is configured to emit red light, blue light, or green light when energized. The organic light-emitting layer 322 may include at least one of a hole injection layer (HIL), a hole transfer layer (HTL), an emitting layer (EML), and an electron transfer layer (ETL). The cathode 323 is arranged on a side of the organic light-emitting layer 322 away from the anode 321. A material of the cathode 323 includes, but is not limited to, chromium, titanium, gold, silver, copper, aluminum, ITO, a combination thereof, or other suitable conductive material. The material of the cathode 323 may be the same as or different from that of the anode 321, which may be set according to the actual situation.

In some embodiments, as shown in FIG. 6, an insulating protection layer 324 is further formed on the cathode 323 by the evaporation process. The insulating protection layer 324 extends along the isolation structure 330 to the metal layer 332. The insulating protection layer 324 is configured to provide an insulation protection for the cathode 323 and a conductive enclosure structure.

In some embodiments, as shown in FIG. 7, different subpixels 320 are arranged on each pixel region 300, respectively. The different subpixels 320 include a red subpixel, a green subpixel, and a blue subpixel.

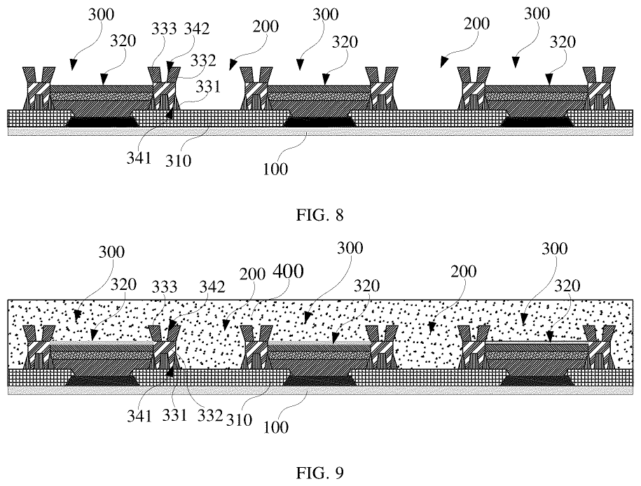

In some embodiments, as shown in FIG. 8, a first hole 341 is formed on the first insulating layer 331 by exposing, developing, and etching the first insulating layer 331. A second hole 342 is formed on the second insulating layer 333 by exposing, developing, and etching the second insulating layer 333. The second hole 342 is misaligned with the first hole 341. After the first hole 341 is formed, the metal layer 332 is firstly formed on the first insulating layer 331, the second insulating layer 333 is formed on the metal layer 332, and the second hole 342 is formed on the second insulating layer 333. A stress may be released through each of the first hole 341 of the first insulating layer 331 and the second hole 342 of the second insulating layer 333 when the extensible region 200 is stretched, such that the stress may be released to a greater extent, thereby further enhancing the tensile strength of the extension zone 200. In some embodiments, the number of the first holes 341 is two, and there is one second hole 342. The second hole 342 is arranged between the first holes 341 and is misaligned with the first holes 341. The first hole 341 is misaligned with the second hole 342 in a same direction, such that the stress may be released at different positions, thereby dispersing the region where the stress is released. In this way, it may be possible to increase the strength of the isolation structure 330, reduce the risk of collapse of the isolation structure 330 when the stress on the first insulating layer 331 and the stress on the second insulating layer 333 are released at the same time, thus ensuring the stability of the performance of the display panel.

In some embodiments, the second hole 342 may be formed after the cathode 323 is formed. In this way, it may be possible to prevent the cathode material from remaining in the second hole 342 during the evaporation process, thereby ensuring that the second hole 342 has a good stress-releasing effect. In addition, the second hole 342 may also be formed after the insulating protection layer 324 is formed. In other embodiments, the second hole 342 may also be formed after the cathode 323 and the insulating protection layer 324 are formed, and a process operation of removing a residual substance in the second hole 342 is added.

In some embodiments, as shown in FIG. 9, an encapsulation layer 400 is formed on the pixel region 300 and the extensible region. The encapsulation layer 400 is arranged on the isolation structure 330. The encapsulation layer 400 extends to the pixel region 300, so as to cause the encapsulation layer 400 to be encapsulated on the subpixel 320. The encapsulation layer 400 extends to the extensible region 200, so as to cause the encapsulation layer 400 to be filled in the extensible region 200. By arranging the encapsulation layer 400 on the pixel region 300 and the extensible region 200, it may be possible to provide protection for the pixel region 300 and the extensible region 200.

In the embodiments of the present disclosure, the width of the metal layer 332 is less than the width of each of the first insulating layer 331 and the second insulating layer 333, and the width of each of the first insulating layer 331 and the second insulating layer 333 is gradually decreased along the direction close to the metal layer 332. The stress brought by the formed isolation structure 330 may act on the first insulating layer 331 and the second insulating layer 333 of the isolation structure 330 when the display panel is stretched. In this way, the stress may be released through the first insulating layer 331 and the second insulating layer 333, such that the first insulating layer 331 and the second insulating layer 333 may release the certain displacement in the stretching direction, thereby reducing the risk of damage to the extensible region 200 during stretching and ensuring that the extensible region 200 may still be used normally after performing repeated stretching. In addition, the first hole 341 of the first insulating layer 331 is misaligned with the second holes 342 of the second insulating layer 333, so as to reduce the stress concentration, thereby strengthening the strength of the isolation structure 330.

In the present disclosure, unless specified or limited otherwise, terms “arranged” and “connected” etc. should be understood in a broad sense. For example, “connected” may be a fixed connection, a detachable connection, or an integral connection. It can be a mechanical connection or an electrical connection. It may be a direct connection or an indirect connection through an intermediate medium. It may be the communication between interior of two elements or the interaction between two elements. For those ordinary skilled in the art, the specific meanings of the aforementioned terms in the present disclosure may be understood according to specific conditions.

In the description of the specification, descriptions of reference terms “some embodiments”, etc., are intended to indicate that particular features, structures, materials, or characteristics described with reference to the embodiment or example are included in at least one embodiment or example of the present disclosure. In the specification, schematic descriptions of the foregoing terms do not need to aim at a same embodiment or example. Besides, the specific features, the structures, the materials or the characteristics that are described may be combined in a proper manner in any one or more embodiments or examples. Moreover, different embodiments or examples and features of different embodiments or examples described in the specification may be synthesized and combined by those skilled in the art as long as no conflict occurs.

Although the embodiments of the present disclosure are shown and described above, it may be understood that the foregoing embodiments are examples, and cannot be understood as limitations to the present disclosure. Those skilled in the art may make changes, modifications, replacements, and variations to the foregoing embodiments without departing from the scope of the present disclosure. Therefore, any change or modification made according to the claims and the specification of the present disclosure should fall within the scope of the present disclosure.

What is claimed is:

1. A display panel, comprising:
a flexible substrate, arranged with a pixel region and an extensible region;
a subpixel, arranged on the pixel region, and comprising an anode, an organic light-emitting layer, and a cathode stacked in sequence along a direction away from the flexible substrate; and
an isolation structure, arranged on the extensible region, and arranged in a peripheral direction of the subpixel;
wherein the isolation structure comprises a first insulating layer, a metal layer, and a second insulating layer stacked in sequence, the metal layer is electrically connected to the cathode, a hole is defined on at least one of the first insulating layer and the second insulating layer, and a stress on the first insulating layer and/or the second insulating layer is released through the hole in response to the extensible region being in a stretched state.

2. The display panel according to claim 1, wherein the hole comprises:
a first hole, defined on the first insulating layer; and
a second hole, defined on the second insulating layer and misaligned with the first hole portion.

3. The display panel according to claim 2, wherein a width of the metal layer is less than a width of each of the first insulating layer and the second insulating layer, and the width of each of the first insulating layer and the second insulating layer is gradually decreased along a direction close to the metal layer.

4. The display panel according to claim 2, wherein a size of the first hole is gradually decreased along a direction close to a pixel definition layer, and a size of the second hole is gradually decreased along a direction close to the metal layer.

5. The display panel according to claim 2, wherein the first hole and the second hole are arranged in a same direction, and the first hole is misaligned with the second hole in a same axis direction.

6. The display panel according to claim 4, wherein one side of the metal layer is embedded in the first hole, the other side of the metal layer is a plane, and the second insulating layer is arranged on the plane.

7. The display panel according to claim 4, further comprising:
the pixel definition layer, protruding from the extensible region, and extending from the extensible region to an edge of the pixel region to form a pixel accommodating region surrounding the pixel region; and
an encapsulation layer, arranged on the pixel region and the extensible region, and embedded in the second hole.

8. The display panel according to claim 7, wherein the encapsulation layer is arranged on the isolation structure, extends to the pixel region to cause the encapsulation layer to be encapsulated on the subpixel, and extends to the extensible region to cause the encapsulation layer to be filled in the extensible region.

9. The display panel according to claim 7, wherein a first protruding portion is arranged on a side of the metal layer facing the first hole, and the first protruding portion is inserted into the first hole.

10. The display panel according to claim 9, wherein a shape of the first protruding portion is corresponding to a shape of the first hole, a size of the first hole is gradually decreased along a direction close to the pixel definition layer, and a size of the first protruding portion is gradually increased along the direction close to the pixel definition layer.

11. The display panel according to claim 7, wherein the encapsulation layer is arranged with a second protruding portion, and the second protruding portion is embedded in the second hole, so as to maintain the stability of the connection between the metal layer and the first insulating layer.

12. The display panel according to claim 11, wherein a shape of the second protruding portion is corresponding to a shape of the second hole, a size of the second hole is gradually decreased along the direction close to the metal layer, and a size of the second protruding portion is gradually increased along the direction close to the metal layer.

13. The display panel according to claim 7, wherein a material of the pixel definition layer comprises one of an organic material, an organic material with an inorganic coating thereon, and an inorganic material;
the organic material of the pixel definition layer comprises polyimide, and/or the inorganic material of the definition layer comprises silicon oxide, silicon nitride, silicon nitride, magnesium fluoride, or a combination thereof.

14. The display panel according to claim 2, wherein the first hole is configured to communicate with an upper surface of the first insulating layer and a lower surface of the first insulating layer, and the second hole is configured to communicate with an upper surface of the second insulating layer and a lower surface of the second insulating layer.

15. The display panel according to claim 1, wherein the subpixel further comprises an insulating protection layer, arranged on the cathode and extends to the second metal layer along the isolation structure.

16. The display panel according to claim 1, wherein the flexible substrate is a composite film layer comprising a nanocellulose film layer and a barrier film layer, and the nanocellulose film layer is used as a main structure of the flexible substrate.

17. The display panel according to claim 1, further comprising: a pixel definition layer, arranged on the flexible substrate and is configured to cover a part of the anode;
wherein a pixel opening is defined on a recessed part of the pixel definition layer, such that at least a part of the anode is exposed in the pixel opening.

18. A method of manufacturing a display panel, capable of manufacturing a display panel, and the method comprising:
forming an anode on a pixel region;
forming an isolation structure on an extensible region, wherein the isolation structure is arranged in a peripheral direction of a subpixel, and comprises a first insulating layer, a metal layer, and a second insulating layer stacked in sequence;
forming a hole on at least one of the first insulating layer and the second insulating layer, wherein the stress on the first insulating layer and/or the second insulating layer is released through a hole; and
forming an organic light-emitting layer and a cathode on the anode in sequence, wherein the cathode is electrically connected to the metal layer.

19. The method according to claim 18, wherein the forming a hole on at least one of the first insulating layer and the second insulating layer, comprises:
forming a first hole on the first insulating layer by exposing, developing, and etching the first insulating layer;
forming a second hole on the second insulating layer by exposing, developing, and etching, wherein the first hole is misaligned with the second hole.

20. The method according to claim 18, wherein further comprising:
forming an initial pixel definition layer on the anode of the subpixel; and
forming a pixel definition layer by exposing and developing the initial pixel definition layer.
